(19) United States
(12) Patent Application Publication
(10) Pub. No.: US 2016/0211349 A1
(43) Pub. Date: Jul. 21, 2016

(54) SEMICONDUCTOR DEVICE AND A METHOD FOR MANUFACTURING A SEMICONDUCTOR DEVICE

(71) Applicant: Toyota Jidosha Kabushiki Kaisha, Toyota-shi (JP)

(72) Inventors: Yuji Fukuoka, Toyota-shi (JP); Sachiko Aoi, Nagakute-shi (JP); Shinichiro Miyahara, Kariya-shi (JP)

(21) Appl. No.: 14/995,621

(22) Filed: Jan. 14, 2016

(30) Foreign Application Priority Data
Jan. 21, 2015 (JP) 2015-009289

(51) Int. Cl. H01L 29/66; H01L 29/10; H01L 29/78

(52) U.S. Cl. CPC H01L 29/66734; H01L 29/7813; H01L 29/1095

(57) ABSTRACT

A semiconductor device includes a semiconductor substrate, a trench extending from a front surface toward a rear surface side of the semiconductor substrate, and an insulator filled in the trench. The semiconductor substrate is provided with in this order from the rear surface side toward the front surface, an n-type drift region, a p-type base region provided on a front surface side of the drift region, a p-type diffusion region provided on a front surface side of the base region and having a higher impurity concentration than that of the base region. The trench pierces the diffusion region and the base region, and reaches the drift region. A void is provided in a portion of the insulator that is filled between portions of the p-type diffusion region that are exposed on both side surfaces of the trench when seen along a vertical cross section of the semiconductor substrate.

### CROSS-REFERENCE TO RELATED APPLICATION

This application claims priority to Japanese Patent Application No. 2015-009289 filed on Jan. 21, 2015, the contents of which are hereby incorporated by reference into the present application.

### TECHNICAL FIELD

The present application relates to a semiconductor device and a method for manufacturing a semiconductor device

### DESCRIPTION OF RELATED ART

A semiconductor device disclosed in Japanese Patent Application Publication No. 2006-128507 includes a semiconductor substrate, a trench extending from a front surface toward a rear surface side in the semiconductor substrate, and an insulator filled in the trench.

### BRIEF SUMMARY OF INVENTION

In a semiconductor device of Japanese Patent Application Publication No. 2006-128507, an insulator filled in a trench expands and contracts relative to a semiconductor substrate by a temperature change during operation. Further, heating process performed upon manufacturing the semiconductor device causes the insulator filled in the trench to expand and contract relative to the semiconductor substrate. When the insulator filled in the trench expands or contracts relative to the semiconductor substrate, thermal stress acts on the insulator and the semiconductor substrate, and a crack may be generated in the insulator and/or the semiconductor substrate. The present specification provides a technique that suppresses a generation of a crack in an insulator and/or a semiconductor substrate.

One aspect of a semiconductor device disclosed in the present specification comprises: a semiconductor substrate; a trench extending from a front surface toward a rear surface side of the semiconductor substrate; and an insulator filled in the trench. The semiconductor substrate comprises, in this order from the rear surface side toward the front surface, an n-type drift region, a p-type base region provided on a front surface side of the drift region, a p-type diffusion region provided on a front surface side of the base region and having a higher impurity concentration than an impurity concentration of the base region. The trench pierces the diffusion region and the base region, and reaches the drift region. A void is provided in a portion of the insulator that is filled between portions of the p-type diffusion region that are exposed on both side surfaces of the trench. The above semiconductor device can be realized by using a phenomenon that a void is formed within the portion of the insulator filled in between the portions of the diffusion region when the impurity concentration of the diffusion region is high.

According to the semiconductor device comprising the above configuration, the void provided within the insulator can relax the thermal stress generated due to the relative expansion or contraction of the insulator, even if the insulator filled in the trench expands or contracts relative to the semiconductor substrate by a temperature change during an operation of the semiconductor device. Due to this, the thermal stress acting on the insulator and the semiconductor substrate can be relaxed, and the generation of a crack in the insulator and/or the semiconductor substrate can be prevented.

The present specification further discloses a novel manufacturing method. A method of manufacturing a semiconductor device disclosed in the present specification comprises: forming a p-type diffusion region in an area of a semiconductor substrate exposed on a front surface of the semiconductor substrate; forming a trench extending from the front surface toward a rear surface side of the semiconductor substrate in the area where the p-type diffusion region is exposed; filling an insulator in the trench; and heating the semiconductor substrate after the filling of the insulator. In the forming of the p-type diffusion region, a void is formed in a portion of the insulator that is filled between portions of the p-type diffusion region that are exposed on both side surfaces of the trench. In so doing, the void is formed within the portion of the insulator filled in the filling thereof, and the thermal stress is relaxed by this void. The thermal stress is relaxed by the void upon when heating is carried out on the semiconductor substrate after the filling in the course of manufacture of the semiconductor device, as a result of which the generation of a crack in the insulator and/or the semiconductor substrate can be prevented.

### BRIEF DESCRIPTION OF DRAWINGS

FIG. 1 is an upper surface view of a semiconductor device of an embodiment;

FIG. 2 is a cross sectional view along II-II in FIG. 1;

FIG. 3 is a diagram (1) explaining a method of manufacturing the semiconductor device;

FIG. 4 is a diagram (2) explaining the method of manufacturing the semiconductor device;

FIG. 5 is a diagram (3) explaining the method of manufacturing the semiconductor device;

FIG. 6 is a diagram (4) explaining the method of manufacturing the semiconductor device;

FIG. 7 is a diagram (5) explaining the method of manufacturing the semiconductor device;

FIG. 8 is a diagram (6) explaining the method of manufacturing the semiconductor device;

FIG. 9 is a diagram explaining the method of manufacturing the semiconductor device (an enlarged view of a primary part IX in FIG. 8);

FIG. 10 is a diagram (7) explaining the method of manufacturing the semiconductor device;

FIG. 11 is a diagram (8) explaining the method of manufacturing the semiconductor device; and

FIG. 12 is a diagram (9) explaining the method of manufacturing the semiconductor device.

### DETAILED DESCRIPTION OF INVENTION

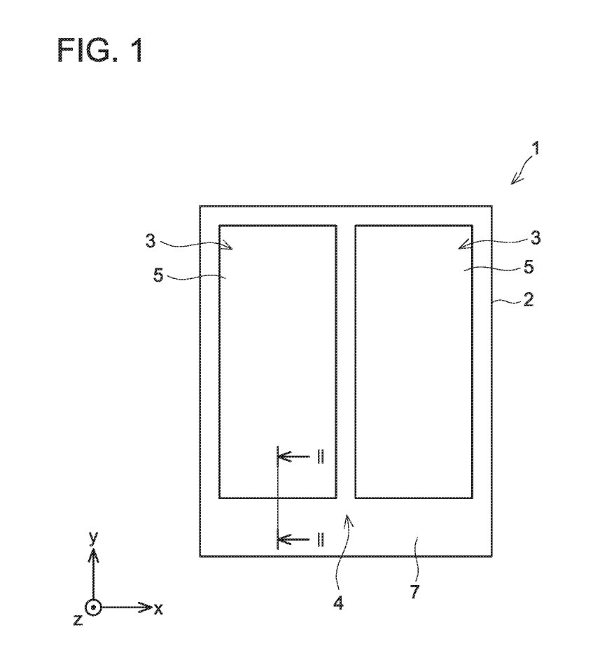

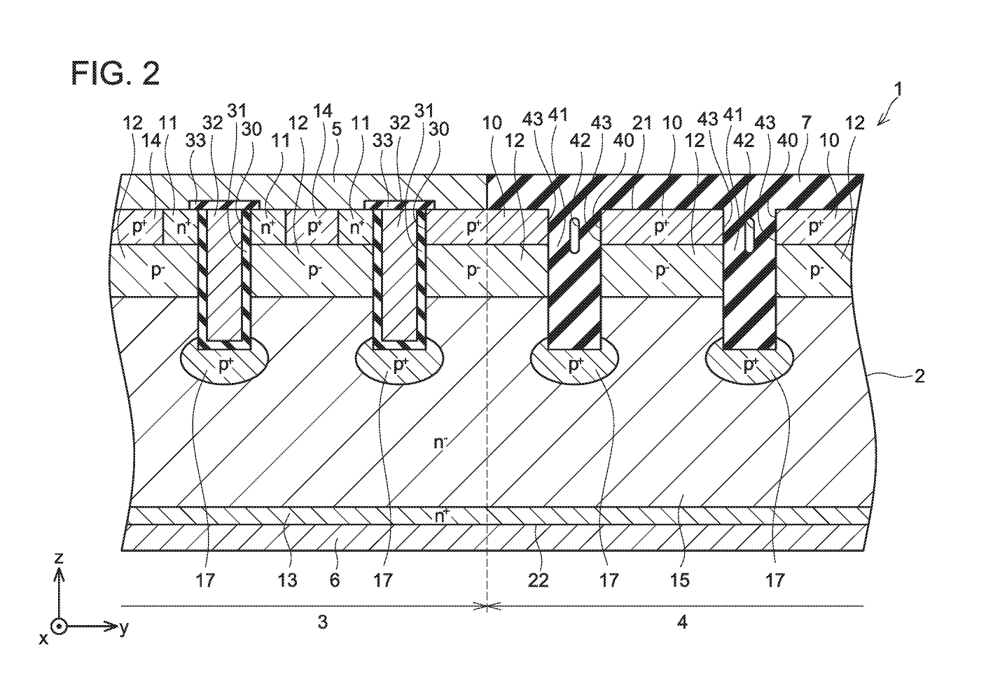

As shown in FIG. 1 and FIG. 2, a semiconductor device 1 of the present embodiment comprises a semiconductor substrate 2, front surface electrodes 5 provided in parts of a front surface 21 of the semiconductor substrate 2, a front surface insulation film 7 provided on another part of the front surface 21, and a rear surface electrode 6 provided on a rear surface 22.

As shown in FIG. 1, the semiconductor substrate 2 has a rectangular shape as seen from its top view. The semiconductor substrate 2 is made of silicon carbide (SiC). The semiconductor substrate 2 comprises element regions 3 and a peripheral region 4. The element regions 3 are positioned on an inner side than the peripheral region 4. The element regions 3 comprise semiconductor elements. In the present embodiment, vertical MOSFETs (Metal Oxide Semiconductor Field Effect Transistors) are provided in the element regions 3. The peripheral region 4 is positioned on an outer side than the element regions 3. A breakdown voltage resisting structure is provided in the peripheral region 4.

As shown in FIG. 2, the front surface electrode 5 is provided on the front surface 21 in each element region 3 of the semiconductor substrate 2. The rear surface electrode 6 is provided on the rear surface 22 over the element regions 3 and the peripheral region 4 of the semiconductor substrate 2. The front surface electrodes 5 and the rear surface electrode 6 are made for example of metal such as aluminum (Al) or copper (Cu).

The front surface insulation film 7 is provided on the front surface of the semiconductor substrate 2 in the peripheral region 4. The front surface insulation film 7 covers the front surface 21 in the peripheral region 4. The front surface insulation film 7 is made for example of silicon oxide (SiO₂). The silicon oxide is deposited on the front surface 21 of the peripheral region 4 of the semiconductor substrate 2.

The semiconductor substrate 2 comprises a plurality of gate trenches 30 and a plurality of terminal trenches 40. The gate trenches 30 are provided in the element regions 3. The terminal trenches 40 are provided in the peripheral region 4.

Further, the semiconductor substrate 2 comprises, in this order from a rear surface 22 side toward the front surface 21, a drain region 13, a drift region 15, and a base region 12. The drain region 13, the drift region 15, and the base region 12 are provided in common for all of the element regions 3 and the peripheral region 4. The semiconductor substrate 2 further comprises source regions 11, contact regions 14, a diffusion region 10, and floating regions 17. The source regions 11 and the contact regions 14 are provided in the element regions 3. The diffusion region 10 is provided in the peripheral region 4. The floating regions 17 are provided respectively in all of the element regions 3 and the peripheral region 4.

In each of the element regions 3, the drain region 13, the drift region 15, and the base region 12 are provided in this order from the rear surface 22 toward the front surface 21 of the semiconductor substrate 2, and the source regions 11 or the contact regions 14 are provided on a front surface side of the base region 12. In the peripheral region 4, the drain region 13, the drift region 15, the base region 12, and the diffusion region 10 are provided in this order from the rear surface 22 toward the front surface 21 of the semiconductor substrate 2.

Each of the gate trenches 30 extends from the front surface 21 toward the rear surface 22 side of the semiconductor substrate 2 (z direction). The gate trenches 30 extend from the front surface 21 of the semiconductor substrate 2 by penetrating the source regions 11 and the base region 12 to positions reaching the drift region 15.

A gate insulation film 31 is provided on an inner surface of each gate trench 30. The gate insulation films 31 are made for example of silicon oxide (SiO₂). A gate electrode 32 is disposed within each gate trench 30. The gate electrodes 32 are filled inside the gate insulation films 31. The gate electrodes 32 are insulated from the semiconductor substrate 2 by the gate insulation films 31. The gate electrodes 32 are made for example of aluminum or polysilicon. An interlayer insulation film 33 is disposed on each gate electrode 32. The gate electrodes 32 and the front surface electrode 5 are insulated by the interlayer insulation films 33.

Each of the terminal trenches 40 extends from the front surface 21 toward the rear surface 22 side of the semiconductor substrate 2 (z direction). The terminal trenches 40 extend from the front surface 21 of the semiconductor substrate 2 by penetrating the diffusion region 10 and the base region 12 to positions reaching the drift region 15. The terminal trenches 40 and the gate trenches 30 have same shape. The terminal trenches 40 are provided at positions separated away from the gate trenches 30. An insulator 41 is filled in the terminal trenches 40. Only the insulator 41 is filled in the terminal trenches 40, and no gate electrode is filled therein.

Silicon dioxide (SiO₂) can be used as the insulator 41. The insulator 41 is made of same material as the front surface insulation film 7 and the gate insulation films 31. The insulator 41 is integrated with the front surface insulation film 7. The insulator 41 makes tight contact with a side surface and a bottom surface of each terminal trench 40. The insulator 41 is filled in each terminal trench 40 from its bottom to an opening potion.

The drain region 13 is an n-type region. The drain region 13 has a high impurity concentration. The drain region 13 is provided on a rear surface side of the drift region 15. The drain region 13 is provided in an area exposed on the rear surface 22 of the semiconductor substrate 2. The drain region 13 makes ohmic contact with the rear surface electrode 6.

The drift region 15 is an n-type region. The drift region 15 has an impurity concentration that is lower than that of the drain region 13. The drift region 15 is provided on a front surface side of the drain region 13. The drift region 15 is provided between the base region 12 and the drain region 13.

The base region 12 is a p-type region. The base region 12 has a low impurity concentration. The p-type impurity concentration of the base region 12 is equal to or less than 1×10¹⁷ [cm⁻³]. The base region 12 is provided in an area on a front surface side of the drift region 15 and making contact with the gate insulation films 31. When a positive voltage is applied to the gate electrodes 32, the base region 12 inverts to an n-type at positions facing the gate electrodes 32 via the gate insulation films 31.

The source regions 11 are n-type regions. The source regions 11 have a high impurity concentration. The source regions 11 are provided in areas on a front surface side of the base region 12 and making contact with the gate insulation films 31. The source regions 11 are provided in island shapes in an area exposed on the front surface 21 of the semiconductor substrate 2. The source regions 11 make ohmic contact with the front surface electrode 5.

The contact regions 14 are p-type regions. The contact regions 14 have a high impurity concentration. The contact regions 14 are provided in areas on the front surface side of the base region 12 and between adjacent source regions 11. The p-type impurity concentration of the contact regions 14 is higher than the p-type impurity concentration of the base region 12. The contact regions 14 are provided next to the source regions 11. The contact regions 14 are provided in island shapes in an area exposed on the front surface 21 of the semiconductor substrate 2. The contact regions 14 make ohmic contact with the front surface electrode 5.

The floating regions 17 are p-type regions. The floating regions 17 have a high impurity concentration. The floating regions 17 are provided around bottoms of the gate trenches 30 and around bottoms of the terminal trenches 40. The floating regions 17 are surrounded by the drift region 15. The floating regions 17 are separated from the base region 12 by the drift region 15. The plurality of floating regions 17 is separated from each other by the drift region 15. Potentials of the floating regions 17 are in a floating state.

The diffusion region 10 is a p-type region. The diffusion region 10 has a high p-type impurity concentration. The p-type impurity concentration of the diffusion region 10 is equal to or less than 1×10¹⁹ [cm⁻³]. The diffusion region 10 is provided on the front surface side of the base region 12. The p-type impurity concentration of the diffusion region 10 is higher than the p-type impurity concentration of the base region 12. The diffusion region 10 is provided in an area that is exposed on the front surface 21 of the semiconductor substrate 2. A front surface and side surfaces of the diffusion region 10 are covered by the insulator 41. The diffusion region 10 is exposed to both side surfaces 43 of each terminal trench 40 as seen in a vertical cross section (FIG. 2). A portion of the diffusion region 10 and a portion of the diffusion region 10 exposed on each side surfaces 43 of each terminal trench 40 face each other in a short direction of the terminal trench 40 (y direction).

A void 42 is provided between the portions of the diffusion region 10 that are exposed on both side surfaces 43 of each terminal trench 40 when seen along the vertical cross section of the semiconductor substrate 2. Each void 42 is provided inside the insulator 41 filled in the corresponding terminal trench 40. The void 42 is formed inside a portion of the insulator 41 that is filled between the portions of the diffusion region that are facing each other when seen along the vertical cross section of the semiconductor substrate 2. The voids 42 are formed at positions in a vicinity of the front surface 21 of the semiconductor substrate 2. Each void 42 is formed at a center portion in a short direction (y direction) of the corresponding terminal trench 40. A width of each void 42 in the short direction (y direction) of the terminal trenches 40 is smaller than a width of the void 42 in a depth direction (z direction) of the terminal trenches 40. An upper end of each void 42 is positioned between the portions of the diffusion region 10 that are exposed on the both side surfaces 43 of the corresponding terminal trench 40 when seen along the vertical cross section of the semiconductor substrate 2. A lower end of each void 42 is positioned between portions of the base region 12 that are exposed on the both side surfaces 43 of the corresponding terminal trench 40 when seen along the vertical cross section of the semiconductor substrate 2. Each void 42 extends continuously in a depthwise direction of a sheet surface of FIG. 2 (x direction). When the impurity concentration of the diffusion region 10 is high, the voids 42 are generated upon filling the insulator 41 in the terminal trenches 40.

In using the semiconductor device 1 having the above configuration, a voltage with which the rear surface electrode 6 is to become positive is applied between the front surface electrode 5 and the rear surface electrode 6. Further, an on-potential (potential that is equal to or more than a potential required for channel formation) is applied to the gate electrodes 32. When the on-potential is applied to the gate electrodes 32, channels are generated in the base region 12 in areas making contact with the gate insulation films 31. Due to this, each MOSFET turns on. In so doing, electrons flow to the rear surface electrode 6 from the front surface electrode 5 via the source regions 11, the channels formed in the base region 12, the drift region 15, and the drain region 13. According to this, current flows from the rear surface electrode 6 to the front surface electrode 5.

As is apparent from the above description, in the aforementioned semiconductor device, the void 42 is formed inside each portion of the insulator 41 filled between the portions of the diffusion region 10 that are exposed on the both side surfaces 43 of the corresponding terminal trench 40 when seen along the vertical cross section of the semiconductor substrate 2. Due to this, even if the insulator 41 filled in the terminal trenches 40 expand or contract relative to the semiconductor substrate 2 by the temperature change during the operation of the semiconductor device 1, the voids 42 formed in the insulator 41 can relax the thermal stress generated by the relative expansion or contraction of the insulator 41. Due to this, the stress acting on the insulator 41 and/or the semiconductor substrate 2 can be mitigated, and the generation of a crack in the insulator 41 and/or the semiconductor substrate 2 can be prevented.

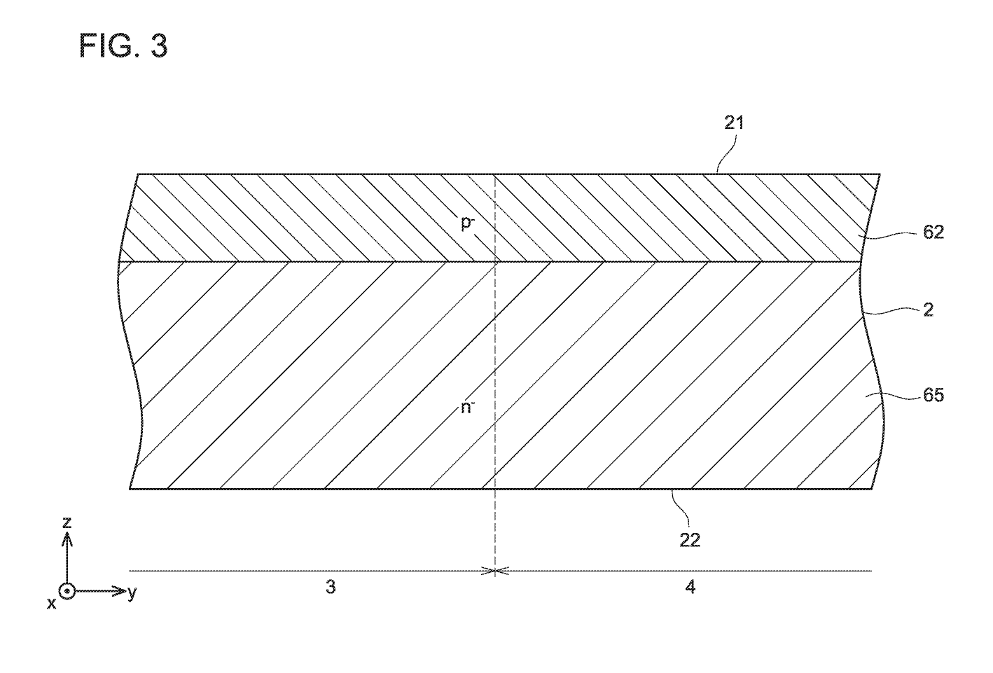

Next, a method of manufacturing a semiconductor device will be described. In manufacturing the aforementioned semiconductor device 1, firstly, as shown in FIG. 3, a p-type semiconductor layer 62 is grown epitaxially on an n-type SiC substrate 65. Due to this, the semiconductor substrate 2 comprising the n-type SiC substrate 65 and the p-type semiconductor layer 62 is formed. The SiC substrate 65 being a lower layer becomes the n-type drift region 15, and the semiconductor layer 62 being an upper layer becomes the p-type base region 12. The base region 12 is formed on the front surface side of the drift region 15.

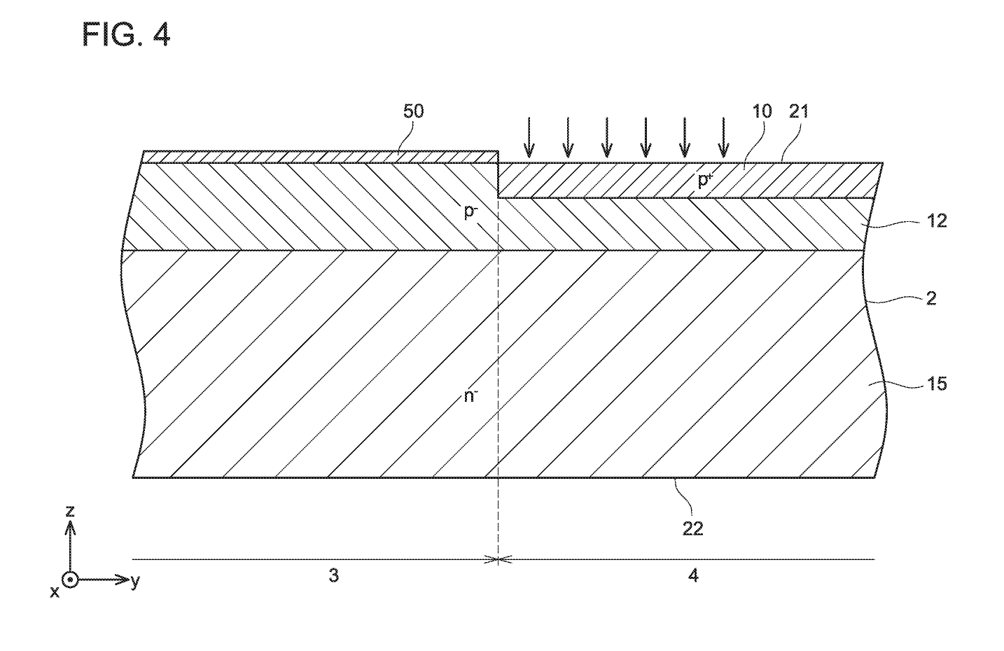

Next, as shown in FIG. 4, a mask 50 is formed on the front surface 21 of the semiconductor substrate 2 for the element regions 3, and the p-type impurities are injected to the front surface 21 of the semiconductor substrate 2 that is exposed from the mask 50. The p-type impurities are injected to the peripheral region 4 of the semiconductor substrate 2. As the p-type impurities, for example, aluminum and boron may be exemplified. Due to this, the p-type diffusion region 10 is formed in an area exposed on the front surface 21 of the semiconductor substrate 2 (diffusion region forming step). The diffusion region 10 is formed on the front surface side of the base region 12. The p-type impurity concentration of the diffusion region 10 is higher than the p-type impurity concentration of the base region 12. The p-type impurity concentration of the diffusion region 10 is at a concentration by which the voids 42 are formed inside the insulator 41 between the portions of the diffusion region 10 facing each other in the filling step to be described later. The mask 50 is removed after having formed the diffusion region 10.

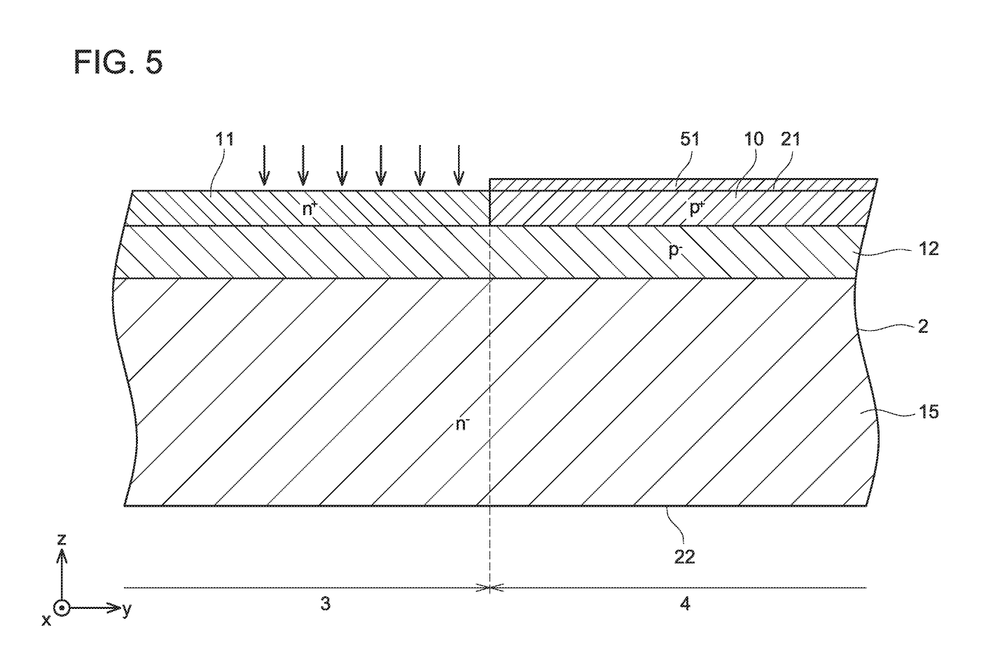

Next, as shown in FIG. 5, a mask 51 is formed on the front surface 21 of the semiconductor substrate 2 for the peripheral region 4, and the n-type impurities are injected to the front surface 21 of the semiconductor substrate 2 that is exposed from the mask 51. The n-type impurities are injected to the element regions 3 of the semiconductor substrate 2. As the n-type impurities, for example, phosphorus may be exemplified. Due to this, the n-type source regions 11 are formed. The n-type source regions 11 are formed on the front surface side of the base region 12. The mask 50 is removed after having formed the source regions 11.

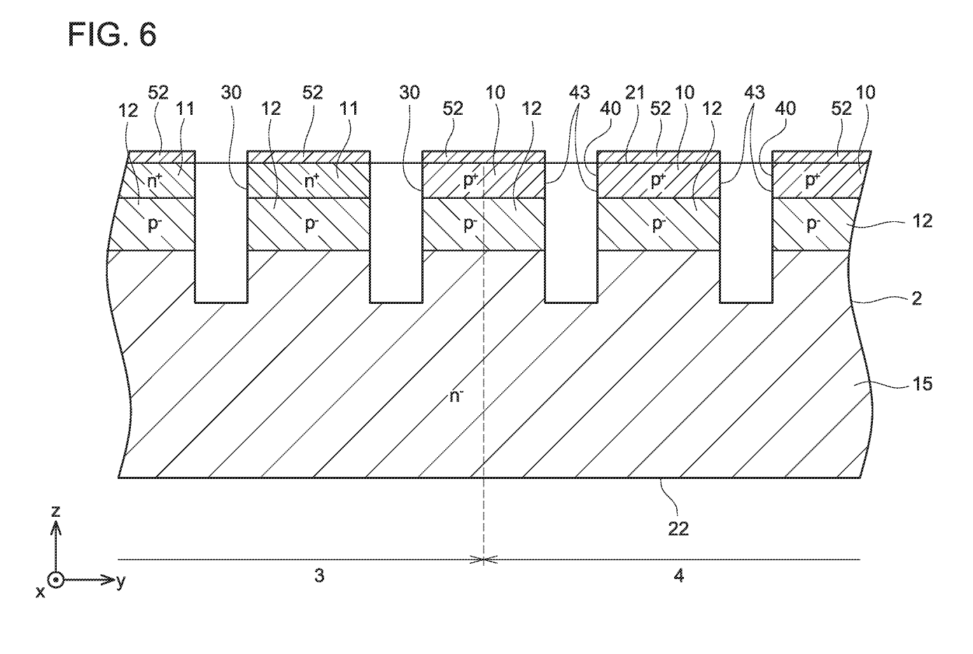

Next, as shown in FIG. 6, a mask 52 is formed on the front surface 21 of the semiconductor substrate 2, and the front surface 21 of the semiconductor substrate 2 exposed from the mask 52 is etched. The front surface 21 of the semiconductor substrate 2 is dug deep in the depth direction (z direction) of the semiconductor substrate 2. In the element regions 3 of the semiconductor substrate 2, the etching is carried out from the front surface 21 of the semiconductor substrate 2, penetrating the source regions 11 and the base region 12, to positions reaching the drift region 15. In the peripheral region 4 of the semiconductor substrate 2, the etching is carried out from the front surface 21 of the semiconductor substrate 2, penetrating the diffusion region 10 and the base region 12, to positions reaching the drift region 15. Due to this, the gate trenches 30 extending toward the rear surface 22 side from the front surface 21 of the semiconductor substrate 2 are formed in the element regions 3. Further, the terminal trenches 40 extending toward the rear surface 22 side from the front surface 21 of the semiconductor substrate 2 are formed in the peripheral region 4 (trench forming step). The portions of the diffusion region 10 are exposed on the both side surfaces 43 of the terminal trenches 40 when seen along the vertical cross section of the semiconductor substrate 2.

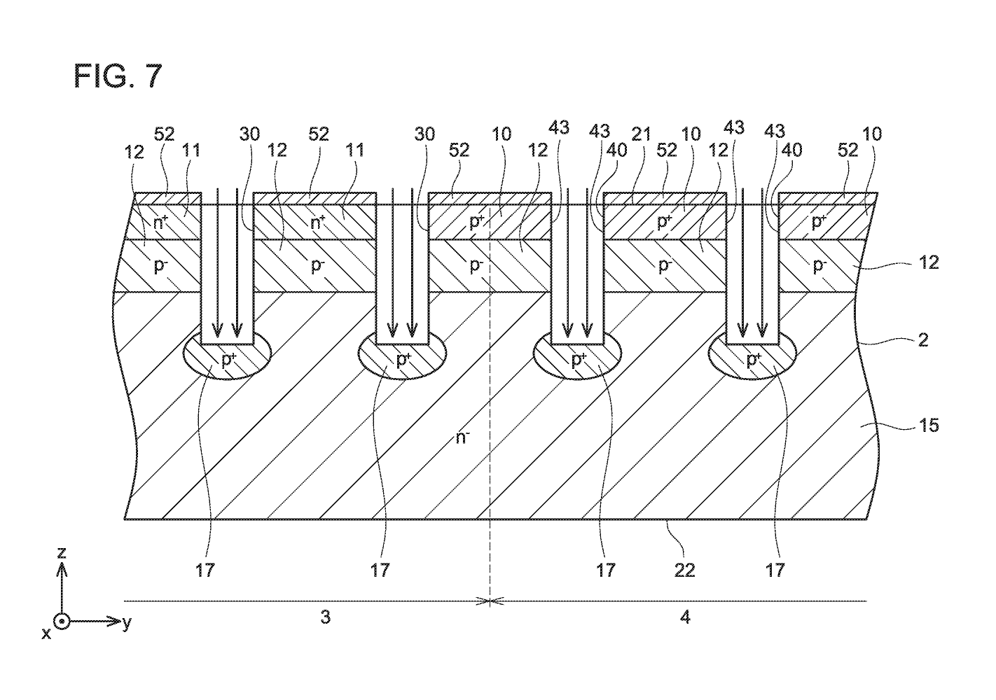

Next, as shown in FIG. 7, the p-type impurities are injected to the bottoms of the gate trenches 30 and the bottoms of the terminal trenches 40. As the p-type impurities, for example, aluminum and boron may be exemplified. Due to this, the floating regions 17 are formed. The floating regions 17 are formed around the bottoms of the gate trenches 30 and around bottoms of the terminal trenches 40. The mask 52 is removed after having formed the floating regions 17.

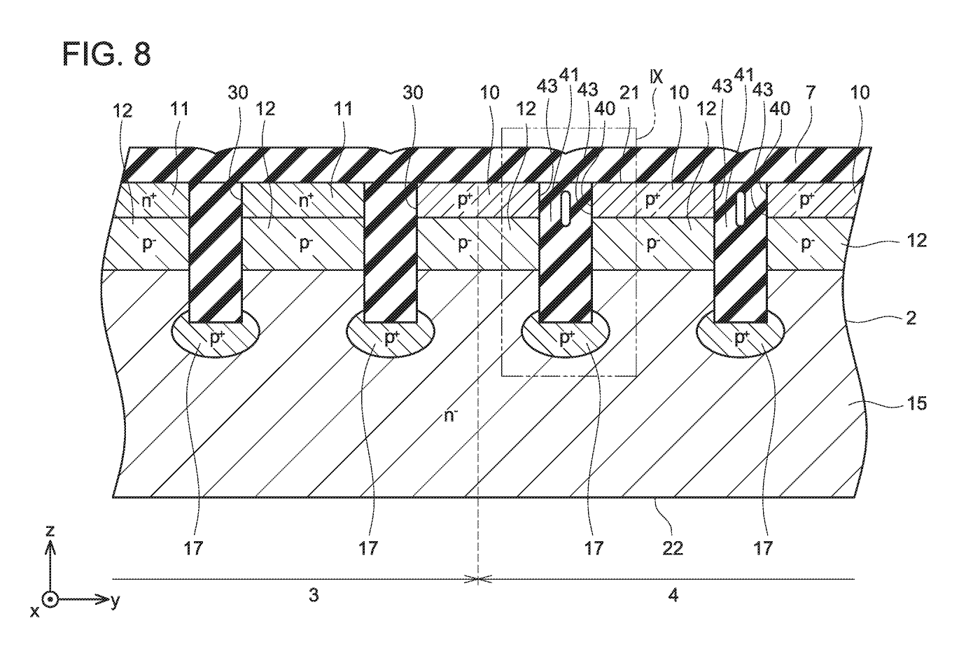

Next, as shown in FIG. 8, an insulator is deposited by a CVD (Chemical Vapor Deposition) method on the semiconductor substrate 2 in which the gate trenches 30 and the terminal trenches 40 have been formed. The insulator is deposited on the front surface 21 of the semiconductor substrate 2, inner surfaces of the gate trenches 30, and inner surfaces of the terminal trenches 40. Due to this, the insulator 41 is filled inside the gate trenches 30 and the terminal trenches 40 (filling step). Further, the front surface 21 of the semiconductor substrate 2 is covered by the front surface insulation film 7.

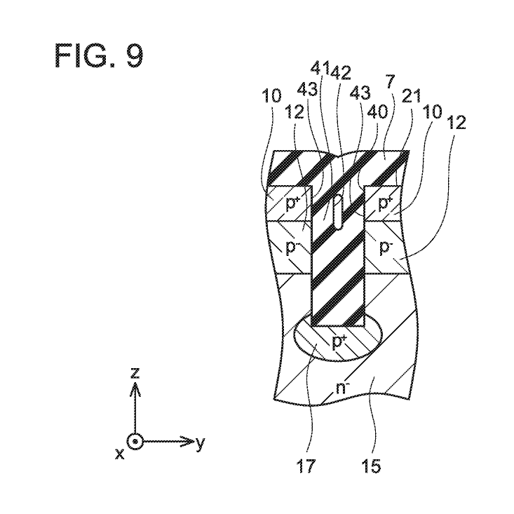

In the filling step, upon when the insulator 41 is deposited in the terminal trenches 40, the voids 42 are formed in the insulator 41 as shown in FIG. 9. Each void 42 is formed between the portions of the diffusion region 10 exposed on the both side surfaces 43 of the corresponding terminal trench 40 when seen along the vertical cross section of the semiconductor substrate 2. In the diffusion region forming step as above, the diffusion region 10 is formed so as to have the p-type impurity concentration with which the voids 42 would be formed in the insulator to be filled between the portions of the diffusion region 10 exposed on the both side surfaces 43 of the terminal trenches 40.

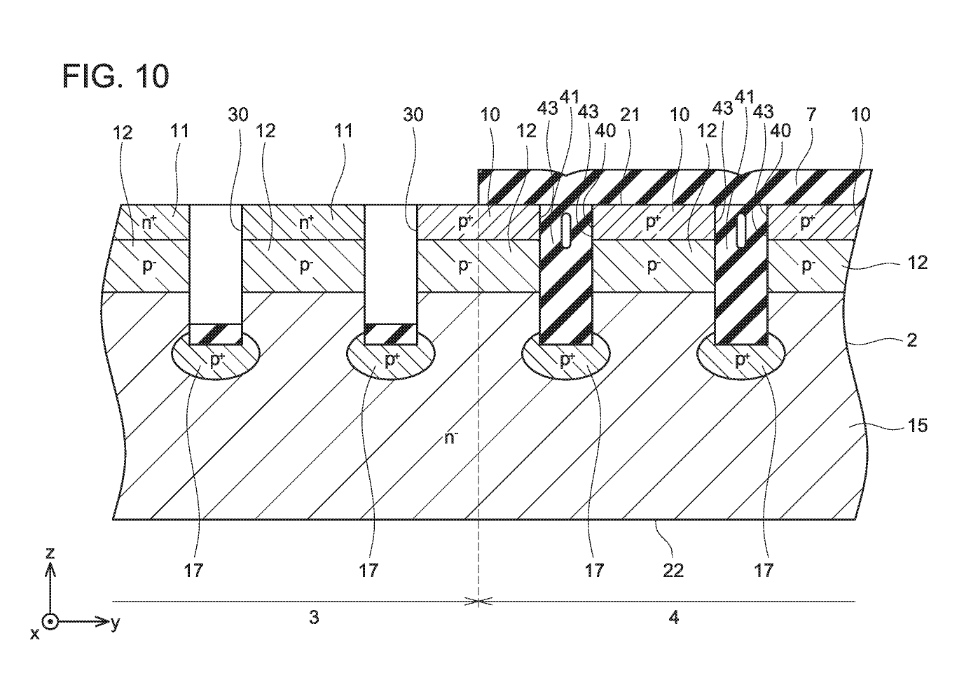

Next, as shown in FIG. 10, the insulator 41 formed on the front surface 21 in the element regions 3 of the semiconductor substrate 2 and the insulator 41 filled in the gate trenches 30 are etched. The unnecessary insulator 41 is removed by the etching.

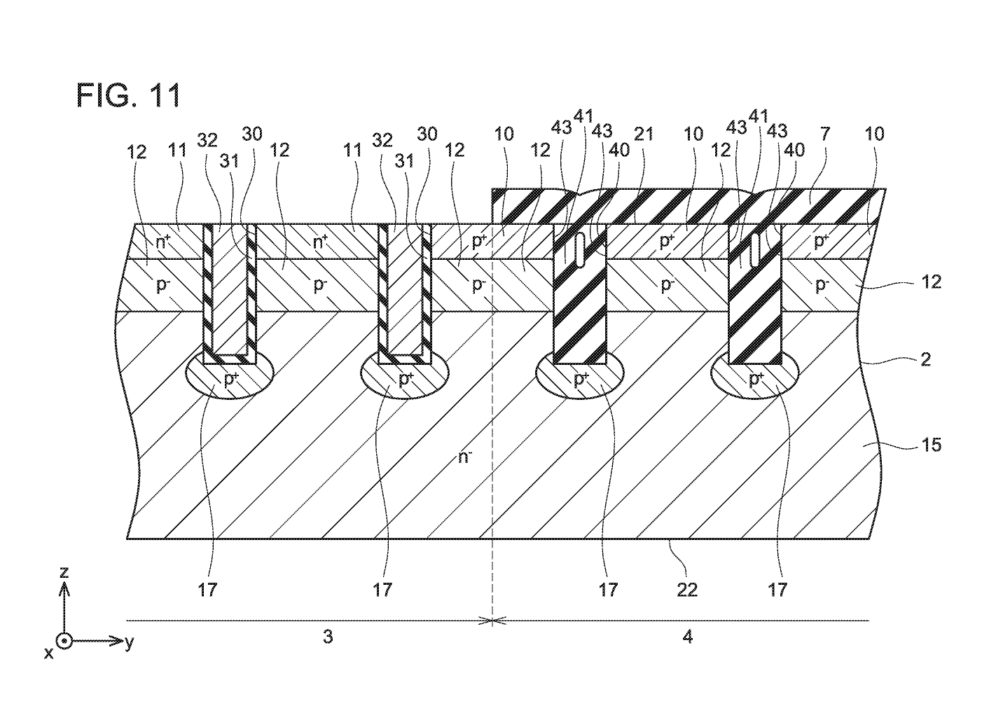

Next, the semiconductor substrate 2 having undergone the filling step is heated (heat treatment step). As shown in FIG. 11, the inner surfaces of the gate trenches 30 are thermally oxidized by the heating, and the gate insulation films 31 are thereby formed. In the heat treatment step, the thermal stress is relaxed by the voids 42 formed in the insulator 41. Thereafter, the gate electrodes 32 are formed in the gate trenches 30 by the CVD method.

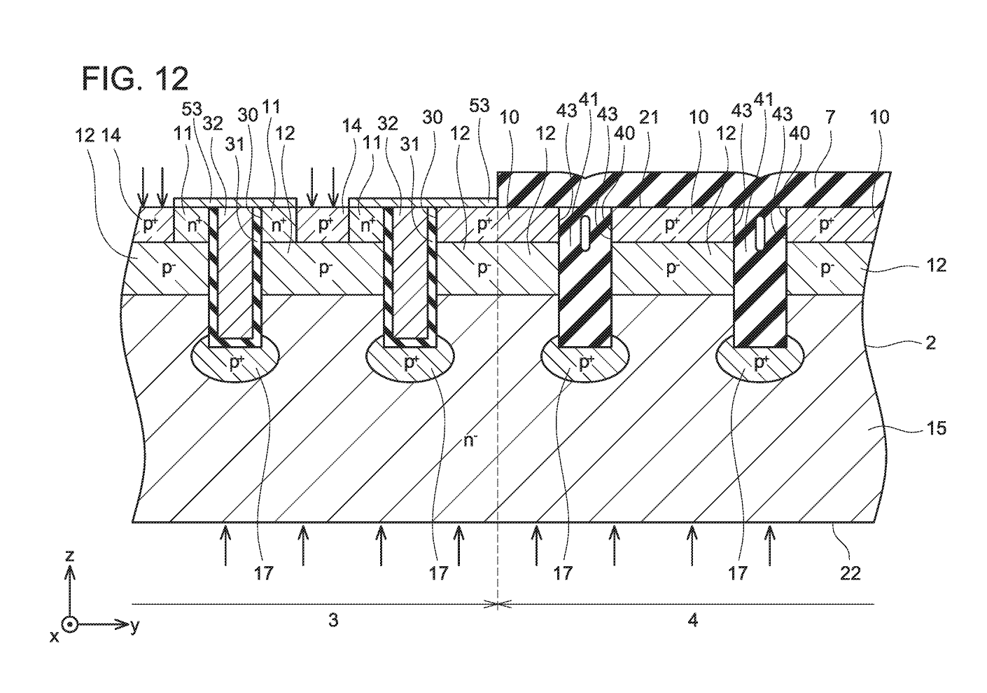

Next, as shown in FIG. 12, a mask 53 is formed on the front surface 21 of the semiconductor substrate 2, and the p-type impurities are injected to the front surface 21 of the semiconductor substrate 2 that is exposed from the mask 53. The p-type impurities are injected to the element regions 3 of the semiconductor substrate 2. As the p-type impurities, for example, aluminum and boron may be exemplified. Due to this, the p-type contact regions 14 are formed. The p-type contact regions 14 are formed on the front surface side of the base region 12. The contact regions 14 are formed next to the source regions 11. The mask 53 is removed after having formed the contact regions 14.

Further, as shown in FIG. 12, the n-type impurities are injected to the rear surface 22 of the semiconductor substrate 2. As the n-type impurities, for example, phosphorus may be exemplified. Due to this, the n-type drain region 13 is formed. The drain region 13 is formed on the rear surface side of the drift region 15.

Subsequently, the interlayer insulation films 33 are formed on the gate electrodes 32. Further, the front surface electrode 5 is formed on the front surface 21 of the semiconductor substrate 2, and the rear surface electrode 6 is formed on the rear surface 22 of the semiconductor substrate 2. According to the above, the semiconductor device 1 as shown in FIG. 2 is manufactured.

According to the aforementioned method of manufacture, upon performing the heat treatment step after having performed the filling step, the voids 42 formed within the insulator 41 can relax the thermal stress generated due to the relative expansion or contraction of the insulator 41, even if the insulator 41 filled in the terminal trenches 40 expands or contracts relative to the semiconductor substrate 2 by the temperature change during the heat treatment step. Due to this, the generation of a crack in the insulator 41 and/or the semiconductor substrate 2 can be prevented.

An embodiment has been described above, however, the specific configuration is not limited to the aforementioned embodiment. For example, in the above embodiment, MOSFETs were described as the semiconductor elements formed in the element regions 3, however, no limitation is made to this configuration. In another embodiment, an IGBT (Insulated Gate Bipolar Transistor) may be used as the semiconductor element.

Specific examples of the present invention has been described in detail, however, these are mere exemplary indications and thus do not limit the scope of the claims The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

An example for the technical elements disclosed in the present specification will herein be explained It should be noted that the respective technical elements are independent of one another, and are useful solely or in combinations.

The semiconductor device may further comprise an front surface insulation film provided on the front surface of the semiconductor substrate, and the front surface insulation film may be integrated with the insulator. This allows for preventing the generation of a crack in the surface insulation film.

What is claimed is:

1. A semiconductor device comprising:
a semiconductor substrate;
a trench extending from a front surface toward a rear surface side of the semiconductor substrate; and
an insulator filled in the trench,
wherein
the semiconductor substrate comprises, in this order from the rear surface side toward the front surface, an n-type drift region, a p-type base region provided on a front surface side of the drift region, a p-type diffusion region provided on a front surface side of the base region and having a higher impurity concentration than an impurity concentration of the base region,
the trench pierces the diffusion region and the base region, and reaches the drift region, and
a void is provided in a portion of the insulator that is filled between portions of the p-type diffusion region that are exposed on both side surfaces of the trench.

2. The semiconductor device according claim 1, further comprising
a front surface insulation film provided on the front surface of the semiconductor substrate, wherein
the front surface insulation film is integrated with the insulator.

3. A method of manufacturing a semiconductor device, the method comprising:
forming a p-type diffusion region in an area of a semiconductor substrate exposed on a front surface of the semiconductor substrate;
forming a trench extending from the front surface toward a rear surface side of the semiconductor substrate in the area where the p-type diffusion region is exposed;
filling an insulator in the trench; and
heating the semiconductor substrate after the filling of the insulator,
wherein
in the forming of the p-type diffusion region, a void is formed in a portion of the insulator that is filled between portions of the p-type diffusion region that are exposed on both side surfaces of the trench, and
in the heating, thermal stress is relaxed by the void.
